(19) United States
(12) Patent Application Publication
(10) Pub. No.: US 2018/0027663 A1
(43) Pub. Date: Jan. 25, 2018

(54) PIN-DIVERGING DEVICE FOR RELEASING STRESSES AND CAPACITOR DETECTION SYSTEM

(71) Applicant: APAQ TECHNOLOGY CO., LTD., MIAOLI COUNTY (TW)

(72) Inventors: MING-GOO CHIEN, TAICHUNG CITY (TW); KUO-CHEN HUANG, CHIAYI COUNTY (TW); MING-TSUNG LIANG, NEW TAIPEI CITY (TW)

(21) Appl. No.: 15/360,725

(22) Filed: Nov. 23, 2016

(30) Foreign Application Priority Data
Jul. 20, 2016 (TW) 105122900

(51) Int. Cl. H05K 3/30; H01G 2/06; C21D 1/30; G01R 31/01

(52) U.S. Cl. CPC H05K 3/303; G01R 31/016; H01G 2/065; C21D 1/30

(57) ABSTRACT

A pin-diverging device for releasing stresses and a capacitor detection system are disclosed. The pin-diverging device includes a pin-diverging module and a heat-generating module adjacent to the pin-diverging module. A capacitor includes two conductive pins respectively passing through two through holes of a seat board, and the two conductive pins of the capacitor are slidably mated with the pin-diverging module so as to diverge the two conductive pins of the capacitor. The seat board is held by the two diverged conductive pins so as to prevent the seat board from being separated from the capacitor. The heat-generating module provides a predetermined heat source to the capacitor so as to release stresses in the capacitor.

### BACKGROUND OF THE INVENTION

### 1. Field of the Invention

The instant disclosure relates to a pin-diverging device and a detection system, and more particularly to a pin-diverging device for releasing stresses and a capacitor detection system.

### 2. Description of Related Art

The winding-type capacitor includes a capacitor core, a casing, and a sealing cover. The capacitor core has an anode foil coupled to an anode terminal, a cathode foil coupled to a cathode terminal, a separator, and an electrolyte layer. The anode foil, the cathode foil and the separator are rolled together. The separator is disposed between the anode foil and the cathode foil. The electrolyte layer is formed between the anode foil and the cathode foil. The casing has an opening for receiving the capacitor core. The sealing cover can be used to seal the casing, and the anode terminal and the cathode terminal can pass through a through hole of the sealing cover. A given space is provided between the sealing cover and the capacitor core. A stopper for securing the space is provided on at least one of the anode terminal and the cathode terminal.

However, the leakage current (LC) of the winding capacitor is increased and a short circuit of the winding capacitor may occur after diverging two pins of the winding capacitor.

### SUMMARY OF THE INVENTION

One aspect of the instant disclosure relates to a pin-diverging device for releasing stresses and a capacitor detection system.

One of the embodiments of the instant disclosure provides a pin-diverging device for releasing stresses, comprising: a pin-diverging module and a heat-generating module adjacent to the pin-diverging module. A capacitor includes two conductive pins respectively passing through two through holes of a seat board, the two conductive pins of the capacitor are slidably mated with the pin-diverging module so as to diverge the two conductive pins of the capacitor, and the seat board is held by the two diverged conductive pins so as to prevent the seat board from being separated from the capacitor. The heat-generating module provides a predetermined heat source to the capacitor so as to release stresses in the capacitor.

Another one of the embodiments of the instant disclosure provides a capacitor detection system, comprising a pin-flattening module, a pin-diverging device, a pin-positioning module, a heat-generating module, and an electrical performance testing module. The pin-flattening module is used for flattening two conductive pins of a capacitor, and the two conductive pins of the capacitor respectively pass through two through holes of a seat board. The pin-diverging module is adjacent to the pin-flattening module for diverging the two conductive pins of the capacitor, and the seat board is held by the two diverged conductive pins so as to prevent the seat board from being separated from the capacitor. The pin-positioning module is adjacent to the pin-diverging module for bending the two conductive pins and positioning the two conductive pins on the seat board. The heat-generating module is adjacent to the pin-diverging module, and the heat-generating module provides a predetermined heat source to the capacitor so as to release stresses in the capacitor. The electrical performance testing module is adjacent to the pin-positioning module for testing the electrical performance of the capacitor.

Yet another one of the embodiments of the instant disclosure provides a pin-diverging device for releasing stresses, comprising: a pin-diverging module and a heat-generating module. The pin-diverging module is used for diverging two conductive pins of a capacitor. The heat-generating module is adjacent to the pin-diverging module, and the heat-generating module provides a predetermined heat source to the capacitor so as to release stresses in the capacitor.

Therefore, the predetermined heat source generated by the heat-generating module can be transmitted to the capacitor for releasing the internal stresses of the capacitor.

To further understand the techniques, means and effects of the instant disclosure applied for achieving the prescribed objectives, the following detailed descriptions and appended drawings are hereby referred to, such that, and through which, the purposes, features and aspects of the instant disclosure can be thoroughly and concretely appreciated. However, the appended drawings are provided solely for reference and illustration, without any intention to limit the instant disclosure.

### BRIEF DESCRIPTION OF THE DRAWINGS

The accompanying drawings are included to provide a further understanding of the instant disclosure, and are incorporated in and constitute a part of this specification. The drawings illustrate exemplary embodiments of the instant disclosure and, together with the description, serve to explain the principles of the instant disclosure.

FIG. 1 shows a lateral, schematic view of the two conductive pins of the capacitor before being flattened according to the first embodiment of the instant disclosure;

FIG. 2 shows a lateral, schematic view of the two conductive pins of the capacitor after having been flattened according to the first embodiment of the instant disclosure;

FIG. 3 shows a perspective, exploded, schematic view of the pin-diverging module according to the first embodiment of the instant disclosure;

FIG. 4 shows a schematic view of the two conductive pins of the capacitor being diverged by the pin-diverging module, and the internal stresses of the capacitor being released by the heat-generating module according to the first embodiment of the instant disclosure;

FIG. 5 shows a lateral, schematic view of the two conductive pins of the capacitor having been diverged according to the first embodiment of the instant disclosure;

FIG. 6 shows a lateral, schematic view of the two conductive pins of the capacitor having been bent and positioned on the seat board according to the first embodiment of the instant disclosure;

FIG. 7 shows a perspective, exploded, schematic view of the pin-diverging module according to the second embodiment of the instant disclosure;

FIG. 8 shows a perspective, assembly, schematic view of the pin-diverging module according to the second embodiment of the instant disclosure;

FIG. 9 shows a schematic view of the two conductive pins of the capacitor being diverged by the pin-diverging module, and the internal stresses of the capacitor being released by the heat-generating module according to the second embodiment of the instant disclosure;

FIG. 10 shows a lateral, assembly, schematic view of the pin-diverging module according to the third embodiment of the instant disclosure;

FIG. 11 shows a schematic view of the two conductive pins of the capacitor being diverged by the pin-diverging module, and the internal stresses of the capacitor being released by the heat-generating module according to the third embodiment of the instant disclosure;

FIG. 12 shows a perspective, assembly, schematic view of the pin-diverging module according to the fourth embodiment of the instant disclosure;

FIG. 13 shows a schematic view of the two conductive pins of the capacitor being diverged by the pin-diverging module, and the internal stresses of the capacitor being released by the heat-generating module according to the fourth embodiment of the instant disclosure;

FIG. 14 shows a perspective, exploded, schematic view of the pin-diverging module according to the fourth embodiment of the instant disclosure;

FIG. 15 shows a perspective, assembly, schematic view of the pin-diverging module according to the fourth embodiment of the instant disclosure;

FIG. 16 shows a partial, cross-sectional, schematic view of the two conductive pins of the capacitor before being diverged by the pin-diverging module according to the fourth embodiment of the instant disclosure;

FIG. 17 shows a partial, cross-sectional, schematic view of the two conductive pins of the capacitor after having been diverged by the pin-diverging module, and the internal stresses of the capacitor being released by the heat-generating module according to the fourth embodiment of the instant disclosure; and

FIG. 18 shows a function block diagram of the capacitor detection system according to the sixth embodiment of the instant disclosure.

### DETAILED DESCRIPTION OF THE PREFERRED EMBODIMENTS

Embodiments of a pin-diverging device for releasing stresses and a capacitor detection system according to the instant disclosure are described herein. Other advantages and objectives of the instant disclosure can be easily understood by one skilled in the art from the disclosure. The instant disclosure can be applied in different embodiments. Various modifications and variations can be made to various details in the description for different applications without departing from the scope of the instant disclosure. The drawings of the instant disclosure are provided only for simple illustrations, but are not drawn to scale and do not reflect the actual relative dimensions. The following embodiments are provided to describe in detail the concept of the instant disclosure, and are not intended to limit the scope thereof in any way.

### First Embodiment

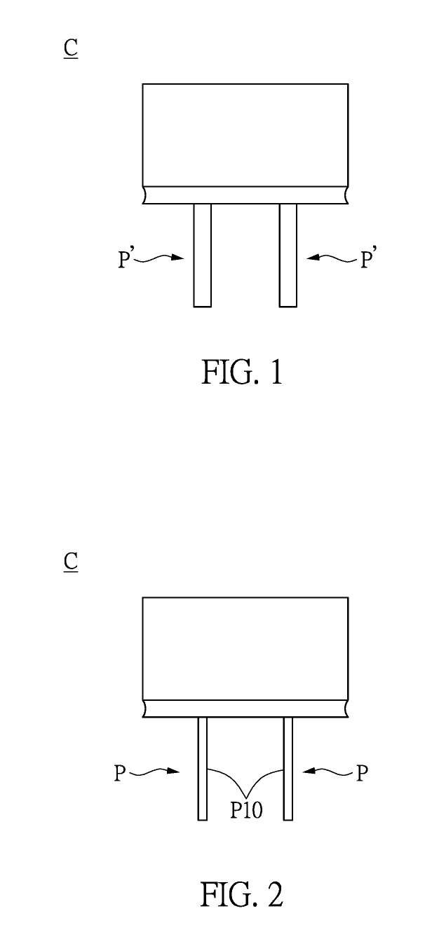

Referring to FIG. 1 to FIG. 6, the first embodiment of the instant disclosure provides a pin-diverging device D for releasing stresses, comprising: a pin-diverging module 2 and a heat-generating module 4 adjacent to the pin-diverging module 2.

First, referring to FIG. 1 and FIG. 2, two cylindrical conductive pins P′ of a capacitor C can be flattened to form two flat-shaped conductive pins P. For example, the capacitor C may be a winding solid electrolytic capacitor, FIG. 1 shows a lateral, schematic view before flattening of the two conductive pins P of the capacitor C according to the instant disclosure, and FIG. 2 shows a lateral, schematic view of the two conductive pins P of the capacitor C after having been flattened according to the instant disclosure. In other words, the two cylindrical conductive pins P′ of the capacitor C can be flattened, so that the shape of the conductive pin can be changed from cylindrical to flat. As shown in FIG. 2, after the cylindrical conductive pin P′ of the capacitor C is flattened to form the flat-shaped conductive pin P, a flattened lateral contact surface P10 is formed on an inner side of the flat-shaped conductive pin P.

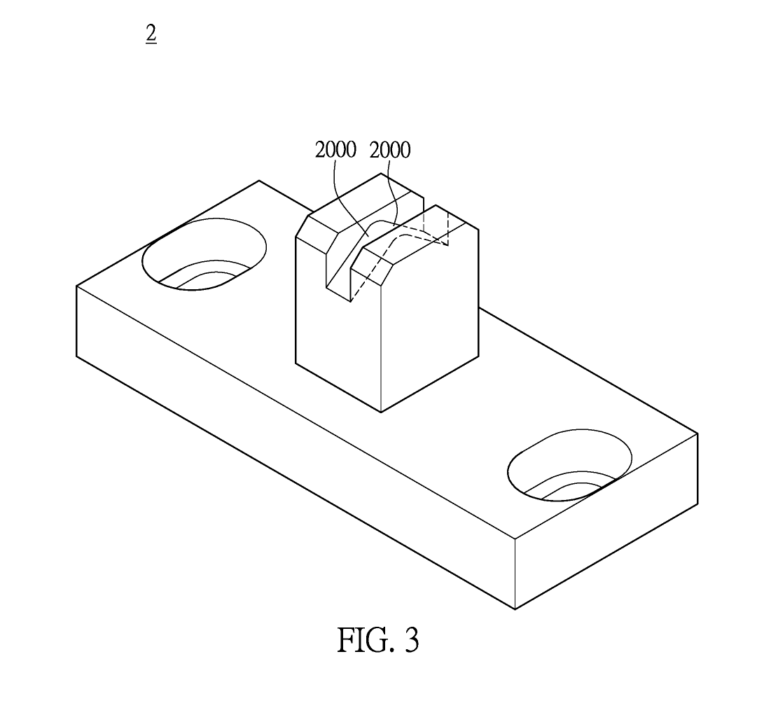

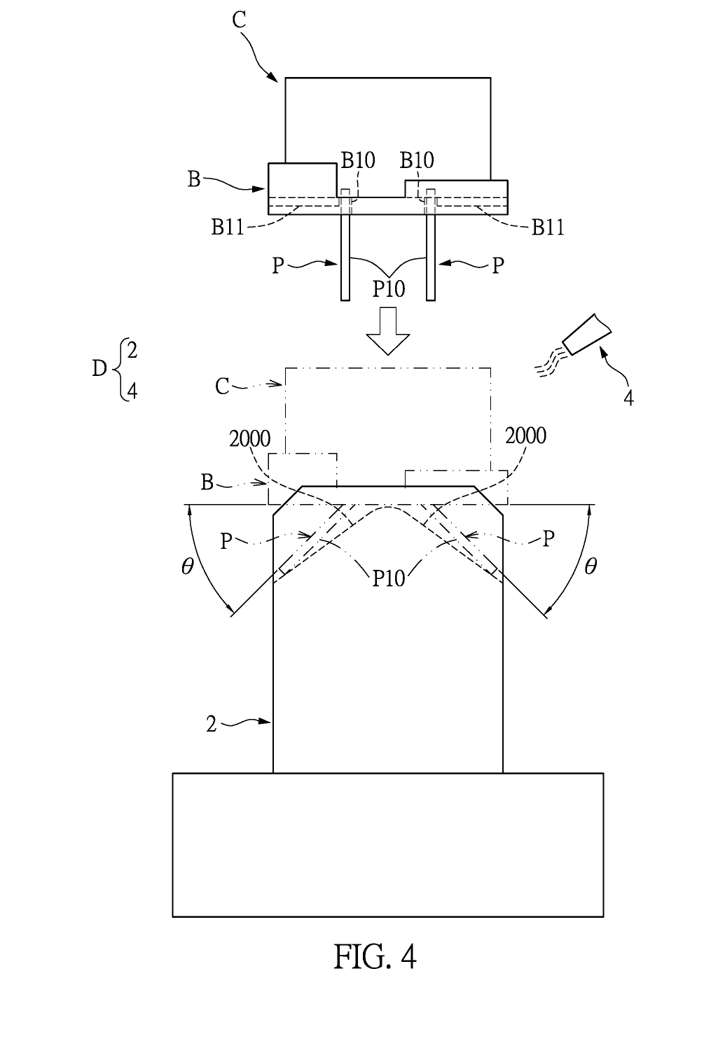

Moreover, referring to FIG. 3 and FIG. 4, the two conductive pins P of the capacitor C respectively pass through two through holes B10 of a seat board B, the two conductive pins P of the capacitor C are slidably mated with the pin-diverging module 2 so as to diverge the two conductive pins P of the capacitor C, and the seat board B is held by the two diverged conductive pins P so as to prevent the seat board B from being separated from the capacitor C. For example, the pin-diverging module 2 has two inclined surfaces 2000, and each conductive pin P has a lateral contact surface P10. The two lateral contact surfaces P10 of the two conductive pins P of the capacitor C concurrently slidably contact the two inclined surfaces 2000 of the pin-diverging module 2 for diverging the two conductive pins P so as to make the two conductive pins P incline toward a bottom side of the seat board B by a predetermined angle θ, so that the seat board B can be held by the two diverged conductive pins P so as to prevent the seat board B from being separated from the capacitor C. Please note that the friction resistance between the conductive pin P and the pin-diverging module 2 can be decreased due to the sliding contact of a small contact area between the lateral contact surface P10 of the conductive pin P and the inclined surface 2000 of the pin-diverging module 2. More precisely, the friction resistance between the conductive pin P and the pin-diverging module 2 is decreased, so that the reaction force applied to the two conductive pins P and the capacitor C due to the sliding contact of a small contact area between the lateral contact surface P10 and the inclined surface 2000 can be decreased (or the structural variation of a junction between the conductive pin P and the capacitor C can be decreased, and an outer force applied to an inner structure of the capacitor C can be decreased). Therefore, the capacitor C provided by the instant disclosure can avoid increasing leakage current (LC) and causing a short circuit.

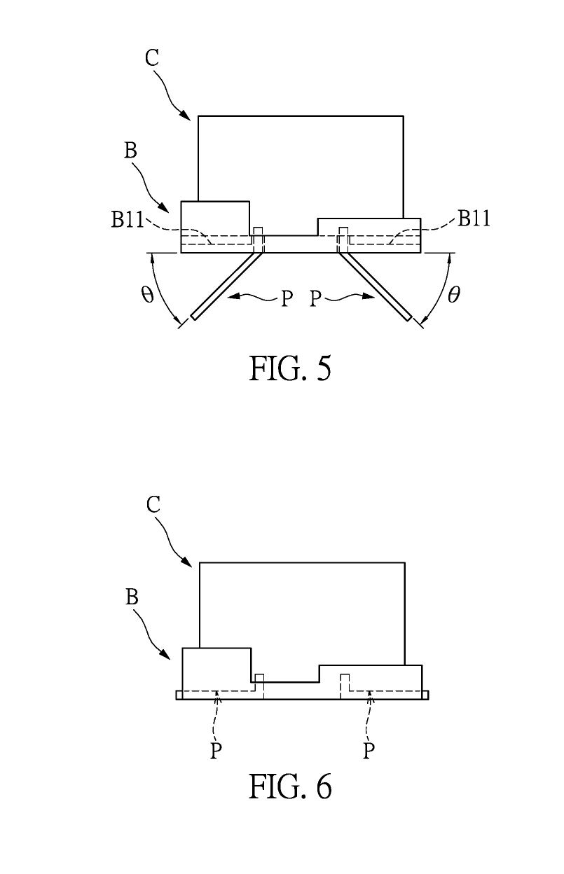

Furthermore, the heat-generating module 4 is disposed close to the pin-diverging module 2. The heat-generating module 4 can provide a predetermined heat source to the capacitor C so as to release stresses in the capacitor C. The stresses in the capacitor C are generated by the reaction force that is applied to the two conductive pins P and the capacitor C due to the sliding contact of a small contact area between the lateral contact surface P10 and the inclined surface 2000. For example, the heat-generating module 4 may be a hot air generator, an infrared generator, or an ultraviolet generator for generating the predetermined heat source. In addition, referring to FIG. 5 and FIG. 6, the two conductive pins P of the capacitor C can be bent and positioned in two positioning grooves B11 of the seat board B.

### Second Embodiment

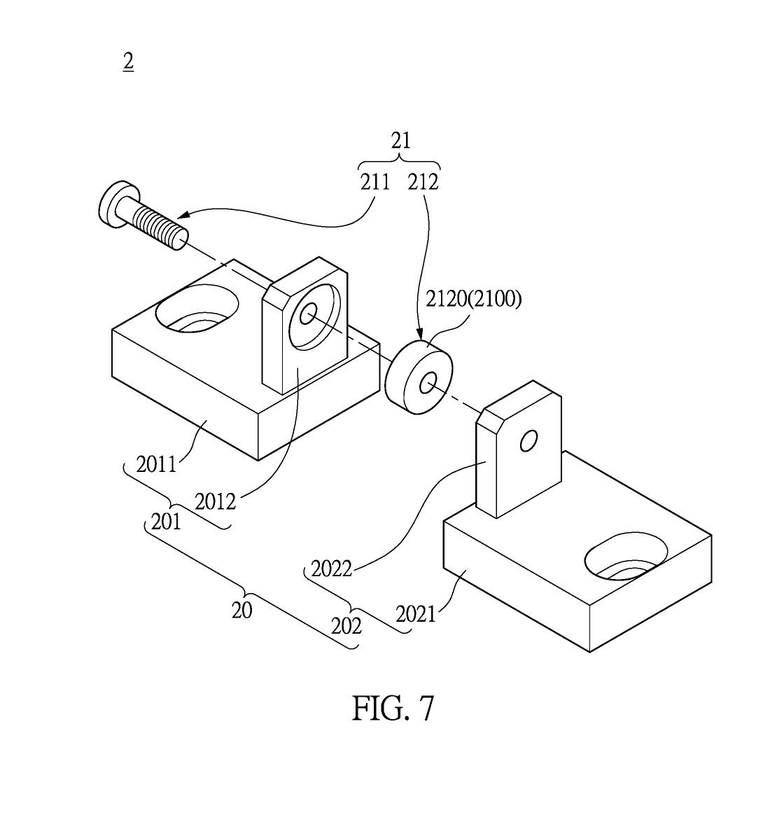

Referring to FIG. 7 to FIG. 9, the second embodiment of the instant disclosure provides a pin-diverging device D for releasing stresses, comprising: a pin-diverging module 2 and a heat-generating module 4 adjacent to the pin-diverging module 2. The difference between the second embodiment and the first embodiment is as follows: in the second embodiment, the pin-diverging device 2 is used to diverge the two conductive pins P of the capacitor C, and the pin-diverging device 2 includes a base structure 20 and a rotatable structure 21. In addition, the rotatable structure 21 is rotatably disposed on the base structure 20, and the rotatable structure 21 has a curved surface 2100. For example, the curved surface 2100 may be a regular curved surface or an irregular curved surface.

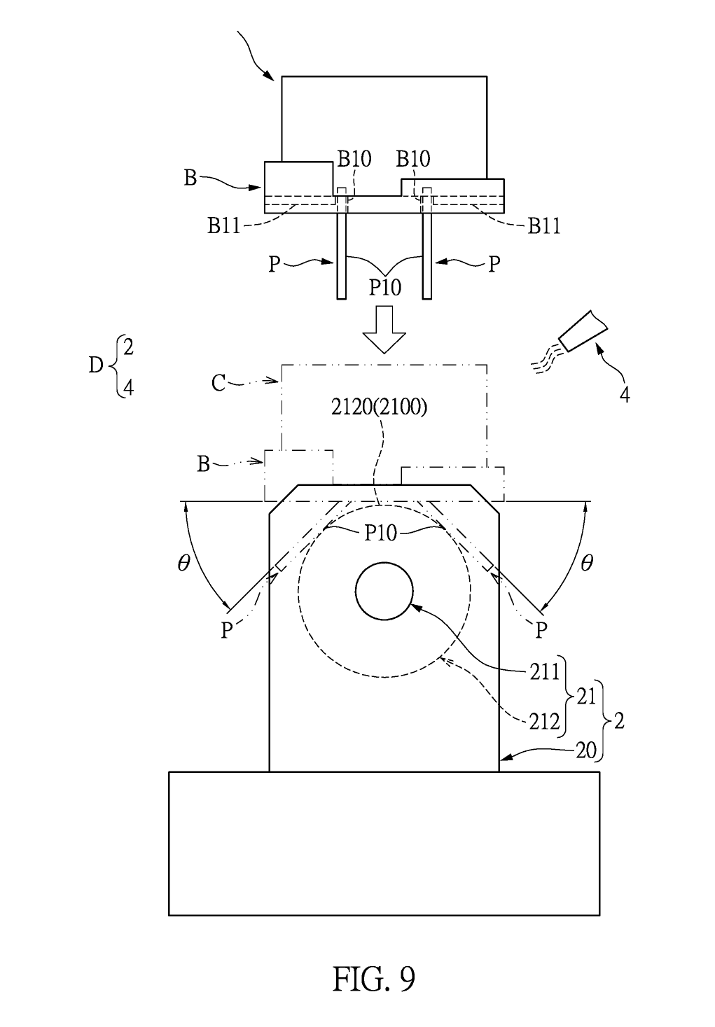

Therefore, as shown in FIG. 9, the two conductive pins P of the capacitor C can respectively pass through two through holes B10 of a seat board B, and each conductive pin P has a lateral contact surface P10. The two lateral contact surfaces P10 of the two conductive pins P of the capacitor C can concurrently slidably contact the curved surface 2100 of the rotatable structure 21 so as to diverge the two conductive pins P of the capacitor C, so that the seat board B can be held by the two diverged conductive pins P so as to prevent the seat board B from being separated from the capacitor C. Please note that the friction resistance between the conductive pin P and the rotatable structure 21 can be decreased due to the sliding contact of a small contact area between the lateral contact surface P10 of the conductive pin P and the curved surface 2100 of the rotatable structure 21. More precisely, the friction resistance between the conductive pin P and the rotatable structure 21 is decreased, so that the reaction force applied to the two conductive pins P and the capacitor C due to the sliding contact of a small contact area between the lateral contact surface P10 and the curved surface 2100 can be decreased (or the structural variation of a junction between the conductive pin P and the capacitor C can be decreased, and an outer force applied to an inner structure of the capacitor C can be decreased). Therefore, the capacitor C provided by the instant disclosure can avoid increasing leakage current (LC) and causing a short circuit.

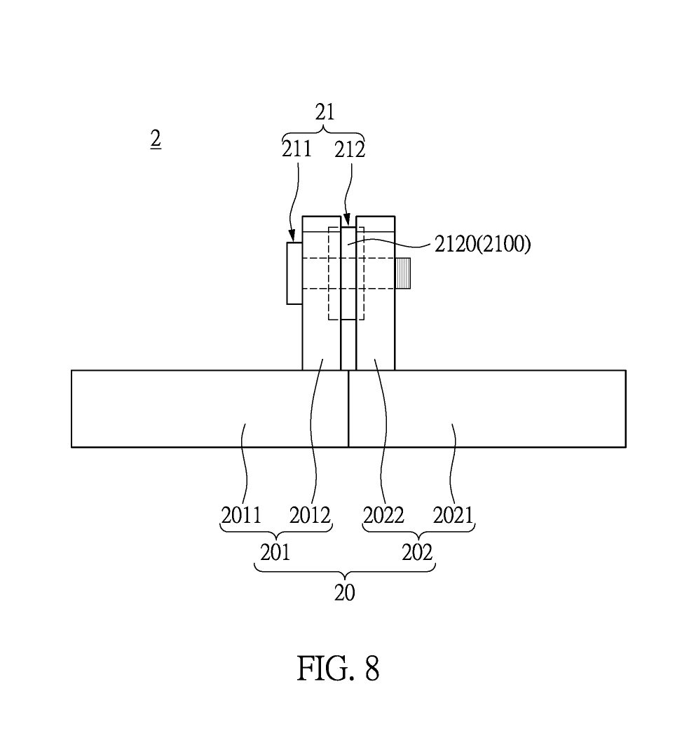

For example, referring to FIG. 7 and FIG. 8, the base structure 20 includes a first base body 201 and a second base body 202 detachably connected to the first base body 201. In addition, the first base body 201 has a first base seat 2011 and a first pivot seat 2012 vertically disposed on the first base seat 2011, the second base body 202 has a second base seat 2021 detachably connected to the first base seat 2011 and a second pivot seat 2022 vertically disposed on the second base seat 2021, and the rotatable structure 21 is pivotably disposed between the first pivot seat 2012 and the second pivot seat 2022.

Following the above description, the rotatable structure 21 includes a pivot axle 211 (such as a fixed axle or a ball-bearing axle) detachably connected between the first pivot seat 2012 and the second pivot seat 2022 and a pivot roller 212 (such as a general roller or a ball bearing) disposed between the first pivot seat 2012 and the second pivot seat 2022 and pivotably disposed around the pivot axle 211. In addition, the curved surface 2100 may be a circular surface 2120 of the pivot roller 212, and the two lateral contact surfaces P10 of the two conductive pins P of the capacitor C can concurrently slidably contact the circular surface 2120 of the pivot roller 212 for diverging the two conductive pins P so as to make the two conductive pins P incline toward a bottom side of the seat board B by a predetermined angle θ, so that the seat board B can be held by the two diverged conductive pins P so as to prevent the seat board B from being separated from the capacitor C. Please note that the friction resistance between the conductive pin P and the pivot roller 212 can be decreased due to the sliding contact of a small contact area between the lateral contact surface P10 of the conductive pin P and the circular surface 2120 of the pivot roller 212. More precisely, the friction resistance between the conductive pin P and the pivot roller 212 is decreased, so that the reaction force applied to the two conductive pins P and the capacitor C due to the sliding contact of a small contact area between the lateral contact surface P10 and the circular surface 2120 can be decreased (or the structural variation of a junction between the conductive pin P and the capacitor C can be decreased, and an outer force applied to an inner structure of the capacitor C can be decreased). Therefore, the capacitor C provided by the instant disclosure can avoid increasing leakage current (LC) and causing a short circuit.

Please note that the heat-generating module 4 can provide a predetermined heat source to the capacitor C so as to release stresses in the capacitor C. The stresses in the capacitor C are generated by the reaction force that is applied to the two conductive pins P and the capacitor C due to the sliding contact of a small contact area between the lateral contact surface P10 and the curved surface 2100 such as the circular surface 2120.

### Third Embodiment

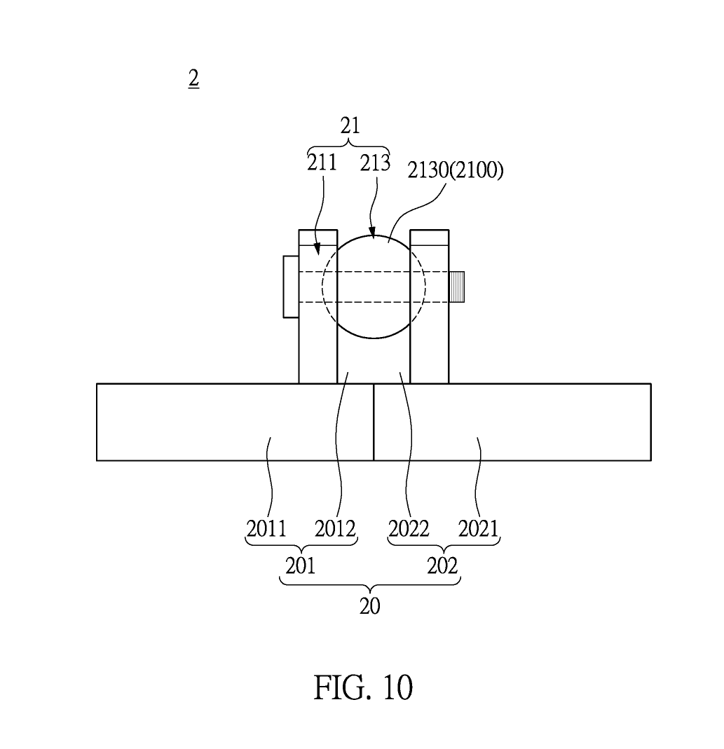

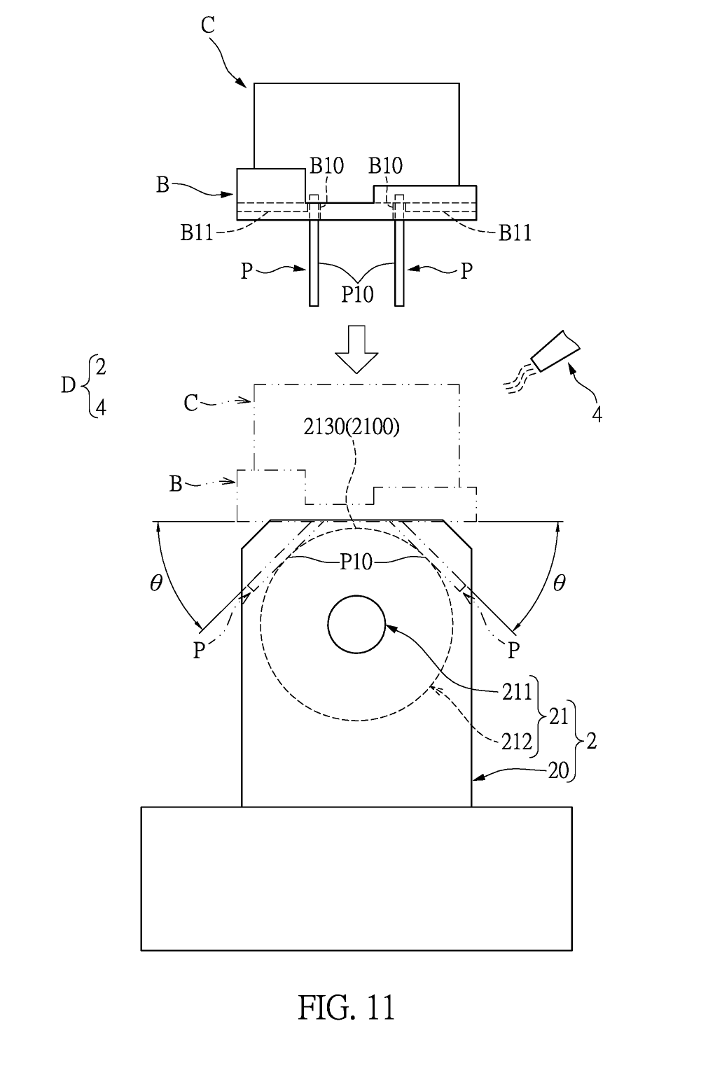

Referring to FIG. 10 and FIG. 11, the third embodiment of the instant disclosure provides a pin-diverging device D for releasing stresses, comprising: a pin-diverging module 2 and a heat-generating module 4 adjacent to the pin-diverging module 2. The difference between the third embodiment and the second embodiment is as follows: in the third embodiment, the rotatable structure 21 includes a pivot axle 211 detachably connected between the first pivot seat 2012 and the second pivot seat 2022 and a pivot ball 213 disposed between the first pivot seat 2012 and the second pivot seat 2022 and pivotably disposed around the pivot axle 211. In addition, the curved surface 2100 may be a spherical surface 2130 of the pivot ball 213, and the two lateral contact surfaces P10 of the two conductive pins P of the capacitor C can concurrently slidably contact the spherical surface 2130 of the pivot ball 213 for diverging the two conductive pins P so as to make the two conductive pins P incline toward a bottom side of the seat board B by a predetermined angle θ, so that the seat board B can be held by the two diverged conductive pins P so as to prevent the seat board B from being separated from the capacitor C. Please note that the friction resistance between the conductive pin P and the pivot ball 213 can be decreased due to the sliding contact of a small contact area between the lateral contact surface P10 of the conductive pin P and the spherical surface 2130 of the pivot ball 213. More precisely, the friction resistance between the conductive pin P and the pivot ball 213 is decreased, so that the reaction force applied to the two conductive pins P and the capacitor C due to the sliding contact of a small contact area between the lateral contact surface P10 and the spherical surface 2130 can be decreased (or the structural variation of a junction between the conductive pin P and the capacitor C can be decreased, and an outer force applied to an inner structure of the capacitor C can be decreased). Therefore, the capacitor C provided by the instant disclosure can avoid increasing leakage current (LC) and causing a short circuit.

### Fourth Embodiment

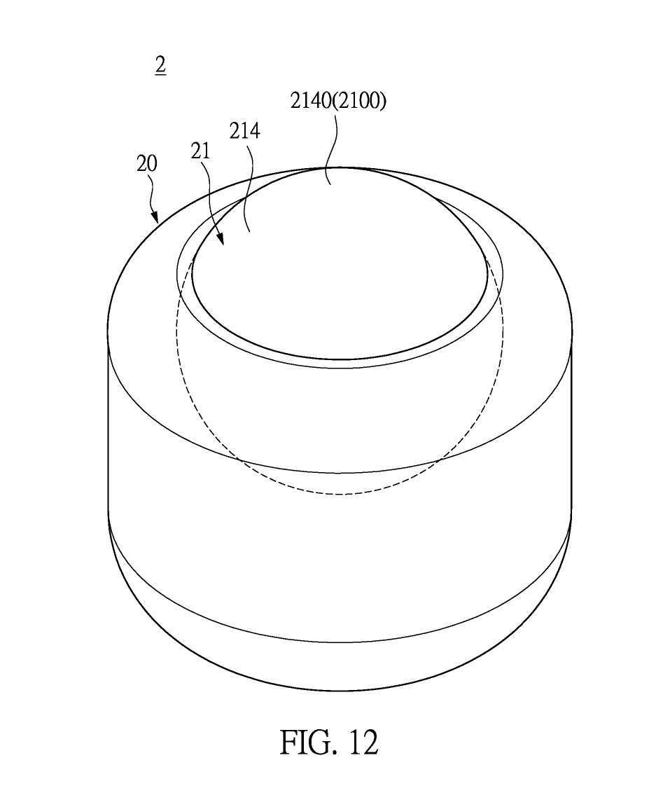

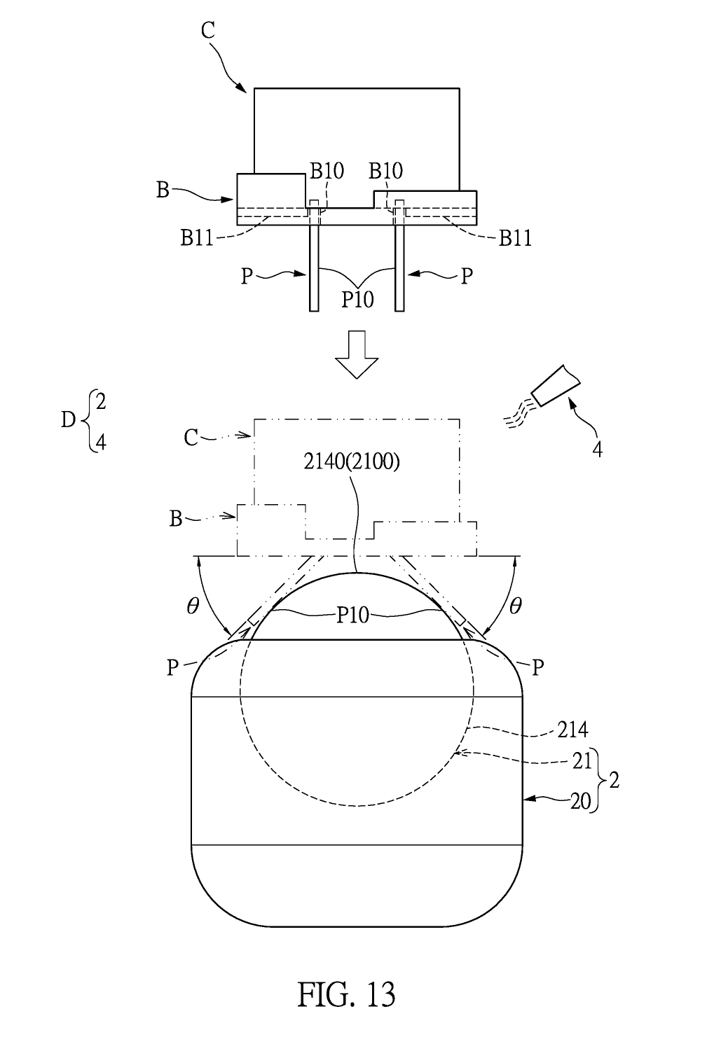

Referring to FIG. 12 and FIG. 13, the fourth embodiment of the instant disclosure provides a pin-diverging device D for releasing stresses, comprising: a pin-diverging module 2 and a heat-generating module 4 adjacent to the pin-diverging module 2. The difference between the fourth embodiment and the second embodiment is as follows: in the fourth embodiment, the rotatable structure 21 includes a rotatable ball 214. In addition, the curved surface 2100 may be a spherical surface 2140 of the rotatable ball 214, and the two lateral contact surfaces P10 of the two conductive pins P of the capacitor C can concurrently slidably contact the spherical surface 2140 of the rotatable ball 214 for diverging the two conductive pins P so as to make the two conductive pins P incline toward a bottom side of the seat board B by a predetermined angle θ, so that the seat board B can be held by the two diverged conductive pins P so as to prevent the seat board B from being separated from the capacitor C. Please note that the friction resistance between the conductive pin P and the rotatable ball 214 can be decreased due to the sliding contact of a small contact area between the lateral contact surface P10 of the conductive pin P and the spherical surface 2140 of the rotatable ball 214. More precisely, the friction resistance between the conductive pin P and the rotatable ball 214 is decreased, so that the reaction force applied to the two conductive pins P and the capacitor C due to the sliding contact of a small contact area between the lateral contact surface P10 and the spherical surface 2140 can be decreased (or the structural variation of a junction between the conductive pin P and the capacitor C can be decreased, and an outer force applied to an inner structure of the capacitor C can be decreased). Therefore, the capacitor C provided by the instant disclosure can avoid increasing leakage current (LC) and causing a short circuit.

### Fifth Embodiment

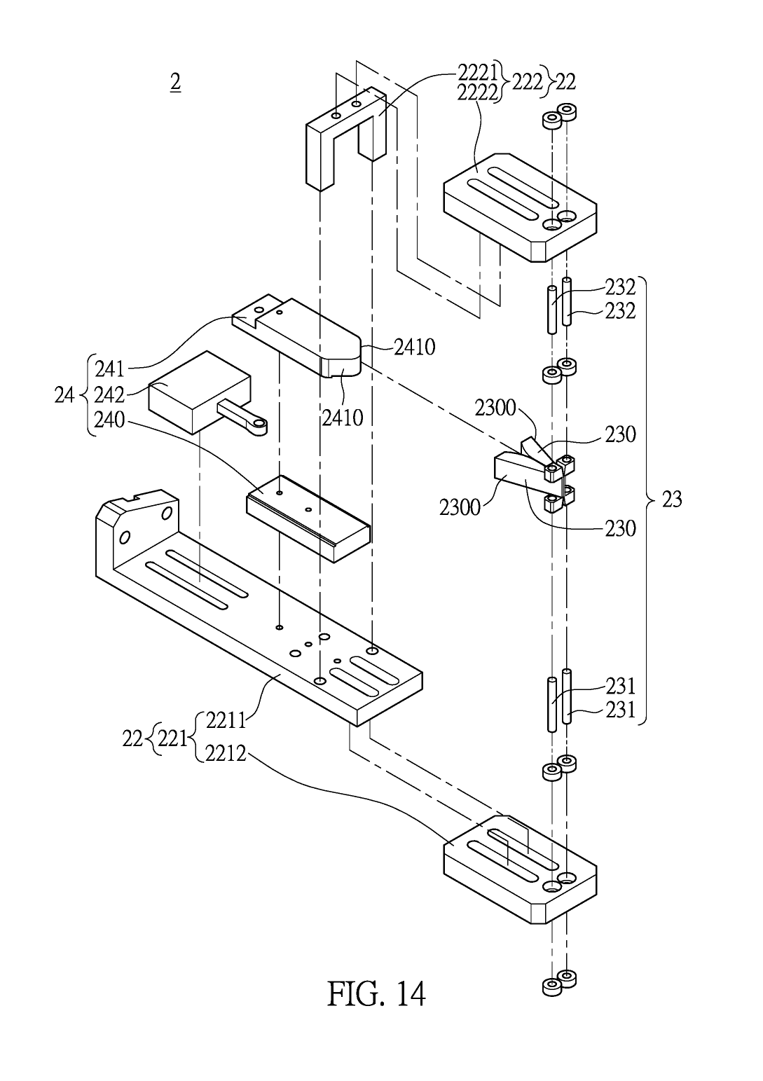

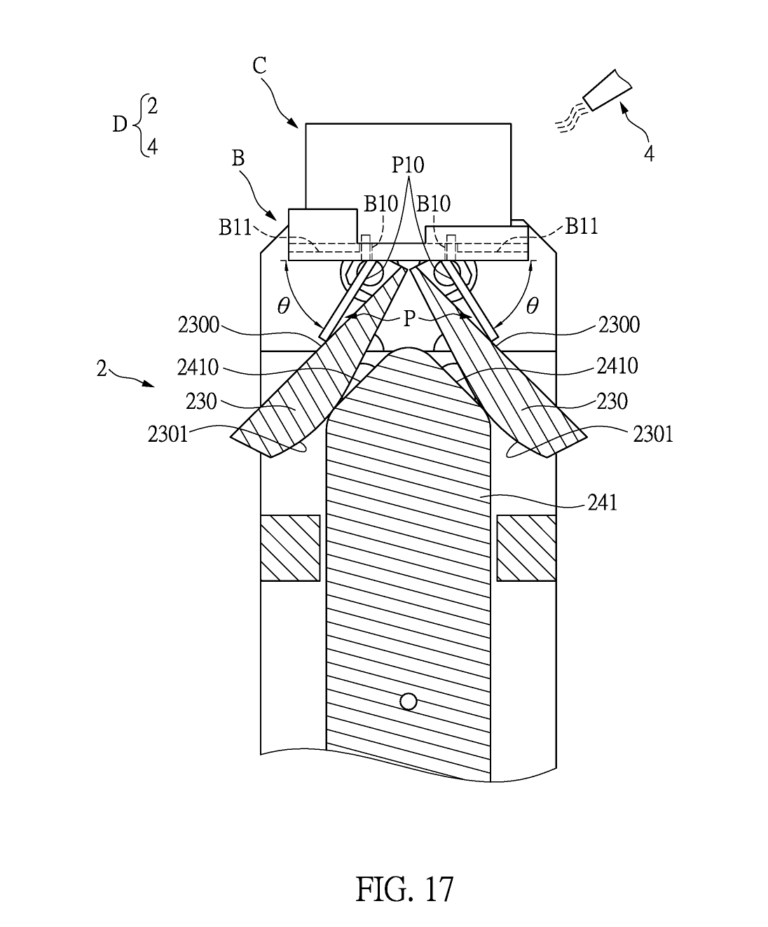

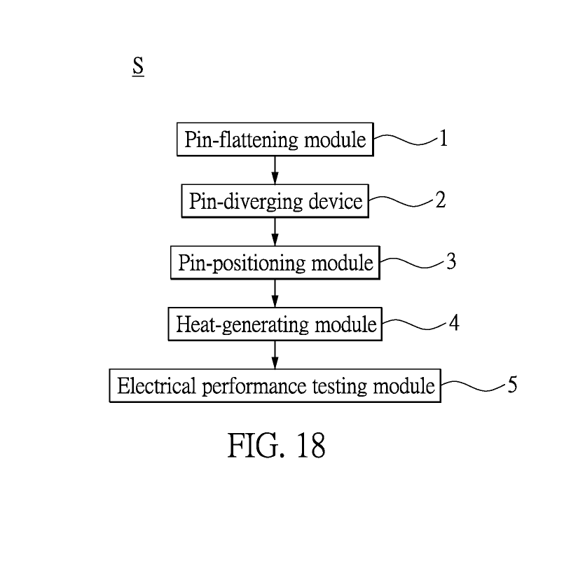

Referring to FIG. 14 and FIG. 17, the fifth embodiment of the instant disclosure provides a pin-diverging device D for releasing stresses, comprising: a pin-diverging module 2 and a heat-generating module 4 adjacent to the pin-diverging module 2. The difference between the fifth embodiment and the first embodiment is as follows: in the fifth embodiment, the pin-diverging module 2 is used for diverging the two conductive pins P of the capacitor C, and the pin-diverging module 2 includes a base structure 22 and a swingable structure 23. In addition, the swingable structure 23 is swingably disposed on the base structure 22, and the swingable structure 23 includes two swingable elements 230.

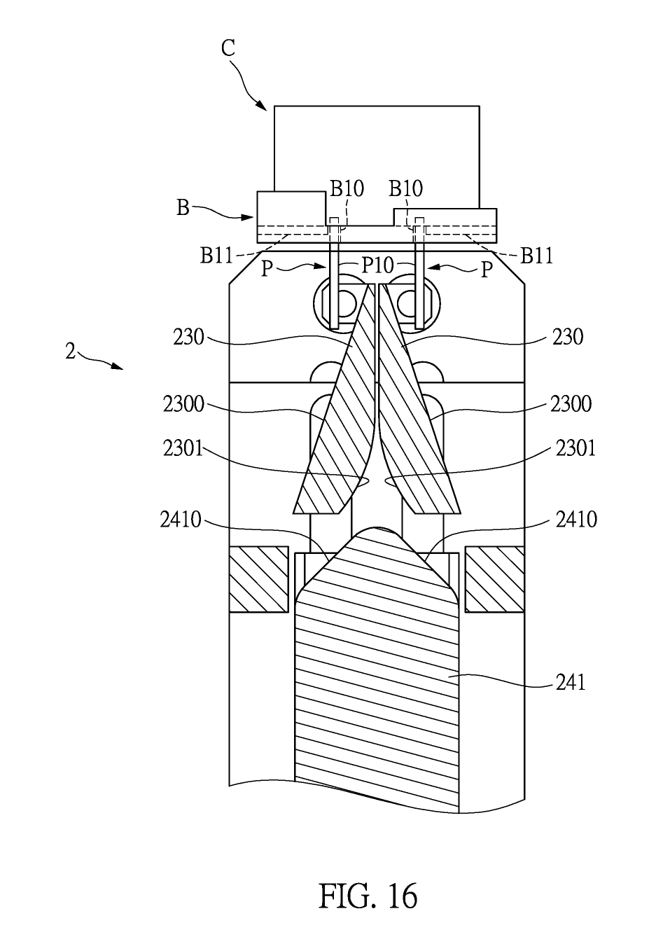

Therefore, referring to FIG. 16 and FIG. 17, the two conductive pins P of the capacitor C can respectively pass through two through holes B10 of a seat board B, and each conductive pin P has a lateral contact surface P10. The two swingable elements 230 of the swingable structure 23 can concurrently slidably contact the two lateral contact surfaces P10 of the two conductive pins P of the capacitor C so as to diverge the two conductive pins P of the capacitor C, so that the seat board B can be held by the two diverged conductive pins P so as to prevent the seat board B from being separated from the capacitor C. Please note that the friction resistance between the conductive pin P and the swingable element 230 can be decreased due to the sliding contact of a small contact area between the lateral contact surface P10 of the conductive pin P and the swingable element 230 of the swingable structure 23. More precisely, the friction resistance between the conductive pin P and the swingable element 230 is decreased, so that the reaction force applied to the two conductive pins P and the capacitor C due to the sliding contact of a small contact area between the lateral contact surface P10 and the swingable element 230 can be decreased (or the structural variation of a junction between the conductive pin P and the capacitor C can be decreased, and an outer force applied to an inner structure of the capacitor C can be decreased). Therefore, the capacitor C provided by the instant disclosure can avoid increasing leakage current (LC) and causing a short circuit.

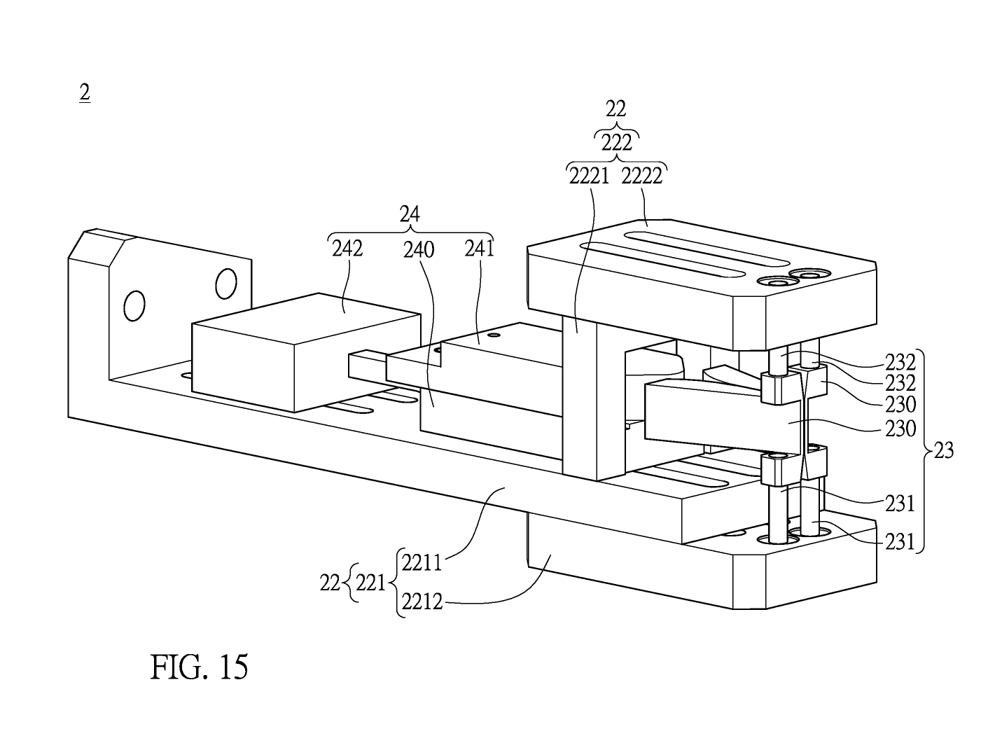

For example, referring to FIG. 14 and FIG. 15, the base structure 22 includes a first base body 221 and a second base body 222 detachably connected to the first base body 221. In addition, the first base body 221 has a first base seat 2211 and a first pivot seat 2212 horizontally disposed on the first base seat 2211, the second base body 222 has a second base seat 2221 detachably connected to the first base seat 2211 and a second pivot seat 2222 vertically disposed on the second base seat 2221, and the swingable structure 23 is pivotably disposed between the first pivot seat 2212 and the second pivot seat 2222.

Following the above description, the swingable structure 23 further includes two first pivot axles 231 detachably connected to the first pivot seat 2212 and two second pivot axles 232 detachably connected to the second pivot seat 2222, one of the two swingable elements 230 is pivotably disposed between one of the two first pivot axles 231 and one of the two second pivot axles 232, and the other swingable element 230 is pivotably disposed between the other first pivot axle 231 and the other second pivot axle 232. Furthermore, the pin-diverging module 2 further comprises a driving structure 24 including a fixed seat 240 detachably disposed on the first base seat 2211, a slidable element 241 slidably disposed on the fixed seat 240, and a driving element 242 disposed on the first base seat 2211 for moving the slidable element 241, and the slidable element 241 has two curved abutting surfaces 2410.

Referring to FIG. 16 and FIG. 17, please note that each swingable element 230 has an inclined surface 2300 and a curved surface 2301 opposite to the inclined surface 2300, the two inclined surfaces 2300 of the two swingable elements 230 are disposed back to back and respectively slidably contact the two lateral contact surfaces P10 of the two conductive pins P of the capacitor C (as shown in FIG. 17), and the two curved surfaces 2301 of the two swingable elements 230 are disposed face to face and respectively correspond to the two curved abutting surfaces 2410 of the slidable element 241 (as shown in FIG. 16). More particularly, as shown in FIG. 17, when the slidable element 241 is moved to concurrently abut against the two swingable elements 230 by the driving element 242, the two curved abutting surfaces 2410 of the slidable element 241 can be respectively abutted against the two curved surfaces 2301 of the two swingable elements 230. Then, the two inclined surfaces 2300 of the two swingable elements 230 can concurrently slidably contact the two lateral contact surfaces P10 of the two conductive pins P of the capacitor C for diverging the two conductive pins P so as to make the two conductive pins P incline toward a bottom side of the seat board B by a predetermined angle θ, so that the seat board B can be held by the two diverged conductive pins P so as to prevent the seat board B from being separated from the capacitor C. Therefore, the friction resistance between the conductive pin P and the swingable element 230 is decreased due to the sliding contact of a small contact area between the lateral contact surface P10 of the conductive pin P and the inclined surface 2300 of the swingable element 230. More precisely, the friction resistance between the conductive pin P and the swingable element 230 is decreased, so that the reaction force applied to the two conductive pins P and the capacitor C due to the sliding contact of a small contact area between the lateral contact surface P10 and the swingable element 230 can be decreased (or the structural variation of a junction between the conductive pin P and the capacitor C can be decreased, and an outer force applied to an inner structure of the capacitor C can be decreased). Therefore, the capacitor C provided by the instant disclosure can avoid increasing leakage current (LC) and causing a short circuit.

Please note that the heat-generating module 4 can provide a predetermined heat source to the capacitor C so as to release stresses in the capacitor C. The stresses in the capacitor C are generated by the reaction force that is applied to the two conductive pins P and the capacitor C due to the sliding contact of a small contact area between the lateral contact surface P10 and the swingable element 230.

### Sixth Embodiment

Referring to FIG. 18, the sixth embodiment of the instant disclosure provides a capacitor detection system S, comprising: a pin-flattening module 1, a pin-diverging module 2, a pin-positioning module 3, a heat-generating module 4, and an electrical performance testing module 5.

First, referring to FIG. 5 and FIG. 18, the pin-flattening module 1 is used for flattening two conductive pins P of a capacitor C, and the two conductive pins P of the capacitor C respectively pass through two through holes B10 of a seat board B. In addition, the pin-diverging module 2 is adjacent to the pin-flattening module 1 for diverging the two conductive pins P of the capacitor C, so that the seat board B can be held by the two diverged conductive pins P so as to prevent the seat board B from being separated from the capacitor C.

Moreover, referring to FIG. 6 and FIG. 18, the pin-positioning module 3 is adjacent to the pin-diverging module 2 for bending the two conductive pins P and positioning the two conductive pins P on the seat board B. For example, the two conductive pins P of the capacitor C can be bent and positioned in two positioning grooves B11 of the seat board B.

Furthermore, referring to FIG. 4 and FIG. 18, the heat-generating module 4 is adjacent to the pin-diverging module 2, and the heat-generating module 4 can provide a predetermined heat source to the capacitor C so as to release stresses in the capacitor C. The stresses in the capacitor C are generated by the reaction force that is applied to the two conductive pins P and the capacitor C due to the sliding contact of a small contact area between the two conductive pins P and the capacitor C.

In addition, referring to FIG. 6 and FIG. 18, the electrical performance testing module 5 is adjacent to the pin-positioning module 3 for testing the electrical performance of the capacitor C. For example, the electrical performance testing module 5 can provide two testing pins (not shown) to electrically contact the two conductive pins P of the capacitor C so as to test the electrical performance of the capacitor C.

In conclusion, the predetermined heat source generated by the heat-generating module 4 can be transmitted to the capacitor C for releasing the internal stresses of the capacitor C.

Moreover, the two lateral contact surfaces P10 of the two conductive pins P of the capacitor C can concurrently slidably contact the curved surface 2100 of the rotatable structure 21 so as to diverge the two conductive pins P of the capacitor C, so that the seat board B can be held by the two diverged conductive pins P so as to prevent the seat board B from being separated from the capacitor C. Please note that the friction resistance between the conductive pin P and the rotatable structure 21 can be decreased due to the sliding contact of a small contact area between the lateral contact surface P10 of the conductive pin P and the curved surface 2100 of the rotatable structure 21. More precisely, the friction resistance between the conductive pin P and the rotatable structure 21 is decreased, so that the reaction force applied to the two conductive pins P and the capacitor C due to the sliding contact of a small contact area between the lateral contact surface P10 and the curved surface 2100 can be decreased (or the structural variation of a junction between the conductive pin P and the capacitor C can be decreased, and an outer force applied to an inner structure of the capacitor C can be decreased). Therefore, the capacitor C provided by the instant disclosure can avoid increasing leakage current (LC) and causing a short circuit.

Furthermore, the two swingable elements 230 of the swingable structure 23 can concurrently slidably contact the two lateral contact surfaces P10 of the two conductive pins P of the capacitor C so as to diverge the two conductive pins P of the capacitor C, so that the seat board B can be held by the two diverged conductive pins P so as to prevent the seat board B from being separated from the capacitor C. Please note that the friction resistance between the conductive pin P and the swingable element 230 can be decreased due to the sliding contact of a small contact area between the lateral contact surface P10 of the conductive pin P and the swingable element 230 of the swingable structure 23. More precisely, the friction resistance between the conductive pin P and the swingable element 230 is decreased, so that the reaction force applied to the two conductive pins P and the capacitor C due to the sliding contact of a small contact area between the lateral contact surface P10 and the swingable element 230 can be decreased (or the structural variation of a junction between the conductive pin P and the capacitor C can be decreased, and an outer force applied to an inner structure of the capacitor C can be decreased). Therefore, the capacitor C provided by the instant disclosure can avoid increasing leakage current (LC) and causing a short circuit.

The aforementioned descriptions merely represent the preferred embodiments of the instant disclosure, without any intention to limit the scope of the instant disclosure which is fully described only within the following claims. Various equivalent changes, alterations or modifications based on the claims of the instant disclosure are all, consequently, viewed as being embraced by the scope of the instant disclosure.

What is claimed is:

1. A pin-diverging device for releasing stresses, comprising:
a pin-diverging module; and
a heat-generating module adjacent to the pin-diverging module;
wherein a capacitor includes two conductive pins respectively passing through two through holes of a seat board, the two conductive pins of the capacitor are slidably mated with the pin-diverging module so as to diverge the two conductive pins of the capacitor, and the seat board is held by the two diverged conductive pins so as to prevent the seat board from being separated from the capacitor;
wherein the heat-generating module provides a predetermined heat source to the capacitor so as to release stresses in the capacitor.

2. The pin-diverging device for releasing stresses of claim 1, wherein the pin-diverging module has two inclined surfaces, each conductive pin has a lateral contact surface, and the two lateral contact surfaces of the two conductive pins of the capacitor concurrently slidably contact the two inclined surfaces of the pin-diverging module so as to diverge the two conductive pins of the capacitor and hold the seat board by the two diverged conductive pins.

3. The pin-diverging device for releasing stresses of claim 1, wherein the pin-diverging module includes:
a base structure; and
a rotatable structure rotatably disposed on the base structure, wherein the rotatable structure has a curved surface;
wherein each conductive pin has a lateral contact surface, and the two lateral contact surfaces of the two conductive pins of the capacitor concurrently slidably contact the curved surface of the rotatable structure so as to diverge the two conductive pins of the capacitor and hold the seat board by the two diverged conductive pins;
wherein the friction resistance between the conductive pin and the rotatable structure is decreased due to the sliding contact between the lateral contact surface of the conductive pin and the curved surface of the rotatable structure.

4. The pin-diverging device for releasing stresses of claim 1, wherein the pin-diverging module includes:
a base structure; and
a rotatable structure rotatably disposed on the base structure, wherein the rotatable structure has a pivot roller, and the pivot roller has a circular surface;
wherein each conductive pin has a lateral contact surface, and the two lateral contact surfaces of the two conductive pins of the capacitor concurrently slidably contact the circular surface of the pivot roller so as to diverge the two conductive pins of the capacitor and hold the seat board by the two diverged conductive pins;
wherein the friction resistance between the conductive pin and the pivot roller is decreased due to the sliding contact between the lateral contact surface of the conductive pin and the circular surface of the pivot roller.

5. The pin-diverging device for releasing stresses of claim 1, wherein the pin-diverging module includes:
a base structure; and
a rotatable structure rotatably disposed on the base structure, wherein the rotatable structure has a pivot ball, and the pivot roller has a spherical surface;
wherein each conductive pin has a lateral contact surface, and the two lateral contact surfaces of the two conductive pins of the capacitor concurrently slidably contact the spherical surface of the pivot ball so as to diverge the two conductive pins of the capacitor and hold the seat board by the two diverged conductive pins;
wherein the friction resistance between the conductive pin and the pivot ball is decreased due to the sliding contact between the lateral contact surface of the conductive pin and the spherical surface of the pivot ball.

6. The pin-diverging device for releasing stresses of claim 1, wherein the pin-diverging module includes:
a base structure; and
a swingable structure swingably disposed on the base structure, wherein the swingable structure includes two swingable elements, and each swingable element has an inclined surface;
wherein each conductive pin has a lateral contact surface, and the two swingable elements concurrently slidably contact the two lateral contact surfaces of the two conductive pins of the capacitor so as to diverge the two conductive pins of the capacitor and hold the seat board by the two diverged conductive pins;
wherein the friction resistance between the conductive pin and the swingable element is decreased due to the sliding contact between the lateral contact surface of the conductive pin and the inclined surface of the swingable element.

7. A capacitor detection system, comprising:
a pin-flattening module for flattening two conductive pins of a capacitor, wherein the two conductive pins of the capacitor respectively pass through two through holes of a seat board;
a pin-diverging module adjacent to the pin-flattening module for diverging the two conductive pins of the capacitor, wherein the seat board is held by the two diverged conductive pins so as to prevent the seat board from being separated from the capacitor;
a pin-positioning module adjacent to the pin-diverging module for bending the two conductive pins and positioning the two conductive pins on the seat board;
a heat-generating module adjacent to the pin-diverging module, wherein the heat-generating module provides a predetermined heat source to the capacitor so as to release stresses in the capacitor; and
an electrical performance testing module adjacent to the pin-positioning module for testing the electrical performance of the capacitor.

8. The capacitor detection system of claim 7, wherein the pin-diverging module includes:
a base structure; and
a rotatable structure rotatably disposed on the base structure, wherein the rotatable structure has a curved surface;
wherein each conductive pin has a lateral contact surface, and the two lateral contact surfaces of the two conductive pins of the capacitor concurrently slidably contact the curved surface of the rotatable structure so as to diverge the two conductive pins of the capacitor and hold the seat board by the two diverged conductive pins;
wherein the friction resistance between the conductive pin and the rotatable structure is decreased due to the sliding contact between the lateral contact surface of the conductive pin and the curved surface of the rotatable structure.

9. The capacitor detection system of claim 7, wherein the pin-diverging module includes:
a base structure; and
a swingable structure swingably disposed on the base structure, wherein the swingable structure includes two swingable elements, and each swingable element has an inclined surface;
wherein each conductive pin has a lateral contact surface, and the two swingable elements concurrently slidably contact the two lateral contact surfaces of the two conductive pins of the capacitor so as to diverge the two conductive pins of the capacitor and hold the seat board by the two diverged conductive pins;
wherein the friction resistance between the conductive pin and the swingable element is decreased due to the sliding contact between the lateral contact surface of the conductive pin and the inclined surface of the swingable element.

10. A pin-diverging device for releasing stresses, comprising:
a pin-diverging module for diverging two conductive pins of a capacitor; and
a heat-generating module adjacent to the pin-diverging module, wherein the heat-generating module provides a predetermined heat source to the capacitor so as to release stresses in the capacitor.
